(19) United States
(12) Patent Application Publication
(10) Pub. No.: US 2021/0280762 A1
(43) Pub. Date: Sep. 9, 2021

(54) THERMOELECTRIC DEVICES AND METHODS OF MAKING SAME

(71) Applicant: Nitto Denko Corporation, Osaka (JP)

(72) Inventor: Kaoru Ueno, Escondido, CA (US)

(21) Appl. No.: 16/325,034

(22) PCT Filed: Aug. 15, 2017
(86) PCT No.: PCT/US2017/046986

§ 371 Date: Feb. 12, 2019

Related U.S. Application Data
(60) Provisional application No. 62/376,309, filed on Aug. 17, 2016.

(51) Int. Cl. H01L 35/34; H01L 35/32; H01L 35/24

(52) U.S. Cl. CPC H01L 35/34; H01L 35/24; H01L 35/32

(57) ABSTRACT

Described herein is a method for making a thermoelectric device, the method comprising: providing a sheet of alternating rows of parallel columns of p- or n-type thermoelectric materials; and electrically communicating the parallel columns such that the rows can be connected in series. Also described is where the columns within each row can also be electrically connected in parallel. Also described herein are thermoelectric devices made according to these methods and/or thermoelectric devices having a similar structure.

### RELATED APPLICATIONS

This application claims the benefit of U.S. Provisional Application No. 62/376,309, filed Aug. 17, 2016, the contents of which are incorporated herein by reference in their entirety.

### BACKGROUND

### Field of Invention

This disclosure relates to thermoelectric devices and fabrication methods of the said thermoelectric devices.

### Description of Related Art

Thermoelectric generation is a technology for directly converting thermal energy into electric energy using the Seebeck effect, i.e. a phenomenon in which an electromotive force is generated in proportion to a temperature difference created between opposite ends of a substance. This technology has been described in United States Patent Publication Number 2008/0230107; United States Patent Publication Number 2008/0303375; United States Patent Publication Number 20110094556; United States Patent Publication Number 2011/0126874; United States Patent Publication Number 2014/0102501; U.S. Pat. No. 7,601,909. However, often times the device may not be flexible, which limits the possible applications or introduces complexities into manufacturing.

Thus, there is a need to enhance the utility of thermoelectric devices by reducing the thickness of the device, and/or increasing the flexibility of the device. In addition, since there are such multitudes of uses, there is a need for a manufacturing method to cheaply and rapidly manufacture flexible thermoelectric devices.

### SUMMARY OF THE INVENTION

Methods for making thermoelectric devices may help to improve the flexibility of the thermoelectric device. Some embodiments include orienting alternating semiconductors orthogonally to the flow of electricity.

In some embodiments, a method for making a thermoelectric device is described, the method comprising (1) providing a sheet of alternating rows of parallel columns of p- or n-type thermoelectric materials; and (2) electrically communicating the parallel columns such that within each row the columns are connected in parallel but the rows are connected in series. In some embodiments, the p-type thermoelectric materials can comprise Bi_{0.5}Sb_{1.5}Te₃. In some embodiments, the n-type thermoelectric materials can comprise Bi₂Se_{0.3}Te_{2.7}. In some embodiments, both p-type and n-type thermoelectric materials also comprise poly(vinylidene fluoride co-hexafluoro-propylene) or P(VDF-HFP). In some embodiments, providing a sheet of alternating rows of parallel columns of p- or n-type thermoelectric materials comprises creating p- or n-type thermoelectric material strips by: (1) hot pressing either p- or n-type thermoelectric materials at 600 MPa to 1000 MPa, at 100° C. to 250° C., for 1 hour to 12 hours and (2) annealing the resulting materials at 275° C. to 400° C. for 30 minutes to 6 hours in a reducing atmosphere.

In some embodiments, providing a sheet of alternating rows of parallel columns of p- or n-type thermoelectric materials comprises placing alternate p- and n-type thermoelectric material strips in parallel and substantially equidistant from one another on a planar surface. In some embodiments, providing a sheet of alternating columns of parallel sheets of p- or n-type thermoelectric materials comprises affixing the alternative p- and n-type materials in parallel and substantially equidistant from one another relationship/position. In some embodiments, providing a sheet of alternating columns of parallel sheets of p- or n-type thermoelectric materials comprises stacking plural sheets to overlap like p- and n-type material on adjacent sheets. In some embodiments, providing a sheet of alternating columns of parallel sheets of p- or n-type thermoelectric materials comprises laminating the stack of plural sheets while retaining the alternative p- and n-type sheets spatial relationships at a temperature between 60° C. to 100° C. for 15 minutes to 45 minutes. In some embodiments, providing a sheet of alternating columns of parallel sheets of p- or n-type thermoelectric materials comprises subsequently curing the stack of plural sheets while retaining the alternative p- and n-type sheets spatial relationships at a temperature between 100° C. to 200° C. for 15 minutes to 45 minutes. In some embodiments, providing a sheet of alternating columns of parallel sheets of p- or n-type thermoelectric materials comprises slicing the stacked plural sheets in an orthogonal orientation to the stacked to create plural thermoelectric sheets.

In some embodiments a thermoelectric sheet device can be described, the device made according to the aforementioned processes. In some embodiments, the device made according to the aforementioned processes is flexible. In some embodiments, a thermoelectric sheet device can be described, the device comprising alternating rows of parallel columns of p- or n-type materials, where said columns within each row are connected electrically in parallel and alternating rows are electrically serially connected.

These and other embodiments are described in more detail herein.

### BRIEF DESCRIPTION OF THE DRAWINGS

FIG. 1 is a schematic of one possible embodiment of the method for making a thermoelectric device.

FIG. 2 is a schematic depicting a possible embodiment of placing p-type material strips and n-type material strips in alternating order in parallel and substantially equidistant on a planar surface. This possible embodiment also shows the option of adding a substrate layer on top to encapsulate the material strips.

FIG. 3 is a depiction of a possible embodiment of a stacked plurality of sheets where the like p- and n-type materials on adjacent sheets overlap, or are registered on top of each other.

FIG. 4 is yet another depiction of a possible embodiment of the stacked plurality of sheets showing alternating rows of parallel spaced apart ribbons of p- or n-type materials within a laminated and cured substrate.

FIG. 5 is a schematic of an embodiment of slicing the thermoelectric stack in an orthogonal orientation to the stack of plural sheets to create plural thermoelectric sheets.

FIG. 6 is a schematic of a resulting thermoelectric sheet.

FIG. 7 is a depiction of yet another embodiment of a thermoelectric sheet showing that the p-type and/or n-type structures can be plural flat ribbon-like/pseudoplanar structures.

FIG. 8 is a depiction of a possible embodiment of a thermoelectric device incorporating the thermoelectric sheet.

FIG. 9 is a schematic of another possible embodiment of a thermoelectric device.

FIG. 10 is a depiction of a possible environment where a thermoelectric device can possibly generate electric power due to the thermal gradient across the device's body.

FIG. 11 is a schematic of yet another possible embodiment of a thermoelectric device, the device being a flexible device mounted on a pipe wall in thermal communication with both a hot and cold working fluid such that heat is transferred between the fluids through the device.

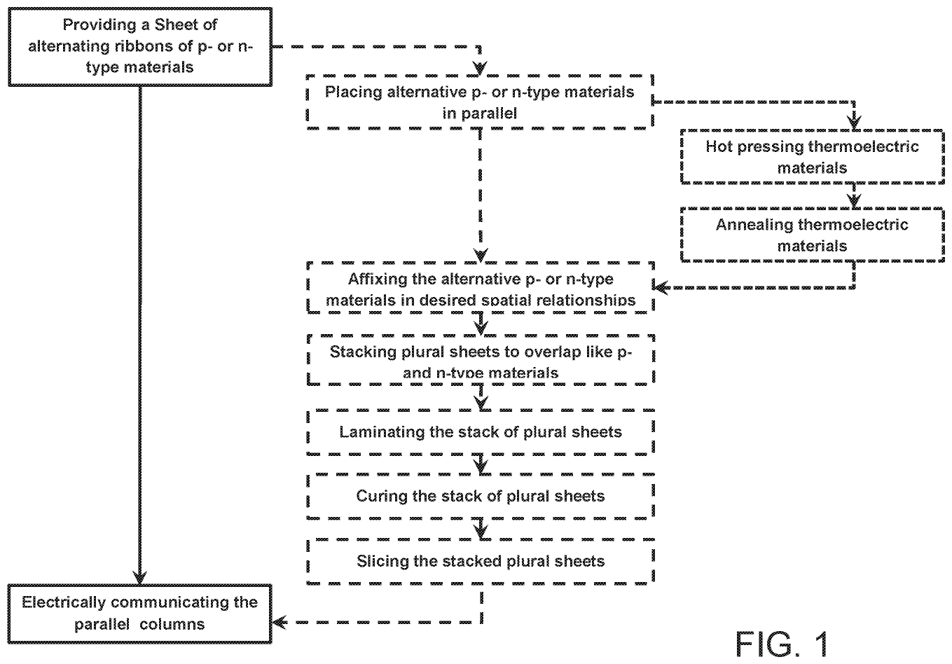

### DETAILED DESCRIPTION

An element may be described as ribbon-shaped if it has a shape that is reasonably recognizable as similar to the shape of a ribbon. This may include elements and/or articles that have a flat rectangular surface that is elongated in one dimension and thin in another dimension. The ribbon shape may also be curved or twisted, so that the element need not be substantially coplanar to be ribbon-shaped.

An element may also be described as pseudoplanar. The term “pseudoplanar” is a broad term that includes elements that are essentially planar. For example, a pseudoplanar article may have a z dimension that is relatively insignificant as compared to the x-y area of the particle that is substantially in the x-y plane.

An element may also be described as “rigid.” The term “rigid” is meant that the material cannot be significantly deformed without observing the formation of cracks or rupture in the monolithic material. In particular, this means that the monolithic material cannot be rolled.

An element may also be described as “flexible.” The term “flexible” is meant that the material can be deformed, in particular wound.

### Method of Making a Thermoelectric Device

In some embodiments, a method for making a thermoelectric device can be described, the method comprising: providing a sheet of rows of parallel spaced apart columns, or ribbons, of thermoelectric materials, where the thermoelectric materials can comprise p- and/or n-type thermoelectric materials forming alternating rows of parallel spaced apart ribbons of thermoelectric p- and/or n-type materials, and electrically communicating the rows in series. In some embodiments, the method can also comprise electrically communicating the parallel columns such that within each row the columns are connected in parallel.

In some embodiments, the method can further comprise first making thermoelectric materials, where making comprises: (1) preparing a thermoelectric powder, creating a thermoelectric slurry, (2) forming the slurry to create a thermoelectric form, and then (3) sintering the form to create a thermoelectric material. In some embodiments, the method varies according to whether the material being made is p-type or n-type (i.e., p-type thermoelectric materials or n-type thermoelectric materials). In some embodiments, the method does not vary rather only the chemical ratios, or inputs into the process.

In some embodiments, the thermoelectric materials described herein can include p-type and/or n-type materials (i.e., p-type thermoelectric materials or n-type thermoelectric materials). In some embodiments the thermoelectric materials can comprise inorganic compounds. In some embodiments, the inorganic compounds may have a suitable crystallinity. In some embodiments, the thermoelectric material, compound or element can comprise bismuth (Bi), antimony (Sb), tellurium (Te), and/or selenium (Se). For example, a formula of the inorganic compound may be A₂M₃ (wherein, A is Bi and/or Sb, and M is Te and/or Se). For example, when a Bi—Te based thermoelectric material is used, thermoelectric performance at around room temperature may be excellent. In some embodiments the inorganic compound can be Bi—Te, Bi—Sb—Te, Bi—Se—Te, or Pb—Ge—Se. In some embodiments, the inorganic compound can be Bi₂Te₃, Bi_{0.5}Sb_{1.5}Te₃ and/or Bi₂Se_{0.3}Te_{2.7}. In some embodiments, the p-type material can comprise Bi_{0.5}Sb_{1.5}Te₃. In some embodiments, the n-type material can comprise Bi₂Se_{0.3}Te_{2.7}.

In some embodiments, preparing a thermoelectric powder can include mechanically alloying elemental powders to form an alloy. In some embodiments, the thermoelectric powder, or p-type and/or n-type material in powered form, can be synthesized starting from the respective elemental materials, e.g., Bi, Sb, Se and Te, using a mechanical alloying ball mill process that results in an ultra fine powder. In some embodiments, Bi, Sb and/or Te, can be ball-milled in molar fractions corresponding to either p-type or n-type materials. In some embodiments, the ball milling can last for at least about 16 hours to at least about 110 hours, or such that the materials have formed their requisite alloy (e.g. Bi_{0.5}Sb_{1.5}Te₃ for p-type and/or Bi₂Se_{0.3}Te_{2.7} for n-type). In some embodiments, ball milling the elemental materials to form an alloy can be between about 500 rpm to about 5000 rpm, or about 1500 rpm. In some embodiments, for the p-type material, the ball milling can be done for at least about 80 hours, at least about 85 hours, at least about 90 hours, at least about 100 hours, at least about 110 hours or any value within that range, for example about 96 hours. The result is a p-type alloy. In some embodiments, for the n-type material, the ball milling can be done for at least about 16 hours, at least about 18 hours, at least about 20 hours, at least about 22 hours, at least about 24 hours or any value within that range, for example about 20 hours. The result is an n-type alloy. In some embodiments, the ball milling can be under a non-oxidizing atmosphere to reduce the oxidizing of the materials. In some embodiments, the non-oxidizing atmosphere can comprise between about 94% to about 100% inert gas and about 0% to about 6% reducing gas. In some embodiments, the inert gas can be argon, or nitrogen. In some embodiments, the reducing gas can be hydrogen and/or oxygen. In one illustrative embodiment, the ball milling process can be conducted in an argon environment with oxygen concentration under about 200 ppm. Associated with the ball milling process, chemical reactions between Bi, Sb and/or Te; Bi, Se, Te powders take place to form the alloys, e.g., Bi_{0.5}Sb_{1.5}Te₃ and/or Bi₂Se_{0.3}Te_{2.7}, in an ultra fine powder form with an average particle size of about 10 nm to about 100 μm, or about 10 nm to about 1 μm, for example about 100 nm. In one illustrative embodiment, the reacted powders are handled in a non-oxidizing environment to prevent oxidation of the semiconductor material prior to the sintering process.

In some embodiments, preparing a thermoelectric powder can further comprise ball milling the alloys to mechanically alloyed powders. In some embodiments, the elemental Bi, Sb, Se and/or Te semiconductor can be ball-milled a time and/or manner sufficient to effect the aforedescribed median size description. In some embodiments, preparing a thermoelectric powder further comprises reducing the semiconductor size population to the aforedescribed ranges, e.g., a median size of about 0.4 μm to about 0.6 μm. In some embodiments, the aforementioned ranges are achieved by ball milling the semiconductor between about 5 hours to about 25 hours, e.g., about 17 hours. In some embodiments, the aforementioned ranges are achieved by ball milling the semiconductor between about 500 rpm to about 5000 rpm, about 1500 rpm. In some embodiments, the aforementioned ranges are achieved by ball milling the semiconductor between about 500 rpm to about 5000 rpm, about 1500 rpm for between about 5 hours to about 25 hours, e.g., about 17 hours.

In some embodiments, the alloys can be acoustically mixed at any one or more intermediate process points before the coating step to average the molecular sizes to help uniformity where there are multiple batches being processed. In some embodiments, acoustic mixing can be for about 10 minutes to about 1 hour, or about 30 minutes. In some embodiments, acoustic mixing can be such that the variation between the mean particle sizes for different samples is less than 10%.

In some embodiments, making thermoelectric materials comprises creating a thermoelectric slurry. In some embodiments, forming the slurry comprises mixing the polymer with the alloy to create a thermoelectric composite. In some embodiments, the alloy can be a p-type material or an n-type material. In some embodiments, the slurry can comprise the aforementioned alloys dispersed within the polymer media. In some embodiments, the polymer can comprise a thermoplastic polymer. In some embodiments, the polymer can be a fluoroelastomer. In some embodiments, the fluoroelastomer can comprise polyvinylidene fluoride (PVDF). In some embodiments, the fluoroelastomer can be a copolymer system comprising vinylidene fluoride and hexapfluoropropylene (VDF/HFP), or poly(vinylidene fluoride co-hexafluoro-propylene) (P(VDF-HFP)). In some embodiments, the fluoroelastomer can comprise PVDF and poly(vinylidene fluoride co-hexafluoro-propylene) (P(VDF-HFP)). In some embodiments, the copolymer system of can comprise vinylidene fluoride and (at least 20%) hexafluoropropylene. In some embodiments, the fluoroelastomer can comprise tetrafluoroethylene (TFE)/propylene. In some embodiments, the fluorelasomer can be TFE/PMVE (perfluoromethylvinyl ether), which creates a perfluorinated fluoroelastomer. In some embodiments, the mass ratio of polymer to alloy can range from about 3:17 to about 3:7, or about 1:3. In some embodiments, the mixture can then be mixed acoustically for about 10 minutes to about 1 hour, or about 30 minutes. In some embodiments, the mixture can also be sonicated for a time ranging from about 30 minutes to about 4 hours, or about 2 hours, to help ensure a uniform mixture. In some embodiments, the slurry can comprise an organic solvent. In some embodiments, the organic solvent can be dimethylformamide (DMF). The result is a thermoelectric slurry.

In some embodiments, forming the slurry to create a thermoelectric form can comprise depositing the slurry on a substrate. In some embodiments, the substrate can comprise an elastomer. In some embodiments, the elastomer can comprise poly(ethylene-vinyl acetate) (PEVA). In some embodiments, the substrate only provides support for the slurry until curing. In other embodiments, the slurry is permanently bonded to the substrate. In some embodiments, depositing the slurry upon the substrate can be by blade coating, spray coating, dip coating, spin coating, tape casting, or other methods known by those skilled in the art. In some embodiments, the resulting coating can have a wet thickness ranging from about 100 μm to about 0.1 mm, or about 400 μm. In some embodiments, the resulting coating can have a dry coating of about 25 μm to about 500 μm, or about 50 μm. The result is a thermoelectric form.

In some embodiments the thermoelectric material can be created by sintering the thermoelectric form. In some embodiments, sintering can be accomplished in two steps: hot pressing and then annealing. In some embodiments, hot pressing the thermoelectric form comprises heating the form in an oven at a temperature ranging between 100° C. to 250° C. In some embodiments, hot pressing the thermoelectric form comprises heating the form at a pressure ranging from about 600 MPa to about 1000 MPa, or 850 MPa. In some embodiments, hot pressing the thermoelectric form can last for a time period between about 1 hour to about 12 hours, or about 2 hours to about 8 hours, or about 4 hours. The result is a pressed form. In some embodiments, the pressed form can then be annealed. In some embodiments, the annealing is performed under a reducing atmosphere. In some embodiments, the reducing atmosphere can be an atmosphere of mixed gas of nitrogen gas (N₂) and hydrogen gas (H₂). In some embodiments, the atmosphere can comprise a 97% N₂/3% H₂ atmosphere. In some embodiments, annealing can be done for a duration ranging from about 30 minutes to about 6 hours, or about 1 hour to about 4 hours, or about 2 hours. In some embodiments, annealing can be done at a temperature of between about 275° C. to about 400° C. In some embodiments, for p-type material, the annealing can be done at a temperature of about 275° C. to about 400° C., or about 375° C. For p-type materials chosen, although performance appears to increase as a function of temperature, higher temperatures result in a more brittle material. In some embodiments, for n-type material, the annealing can be done at a temperature of about 275° C. to about 400° C., or about 325° C. For n-type materials chosen, the thermoelectric form performance appears to peak around 325° C. The result is a thermoelectric material.

In some embodiments, the method can further comprise cutting the thermoelectric materials to create p- or n-type thermoelectric material strips. Cutting can be by any method known by those skilled in the art, including but not limited to: mechanical sawing (e.g. cutting by blade, saw, and the like), electrochemical sawing (e.g. etching, electrical discharge machining), or thermal (e.g. laser, flame cutting, plasma cutting). The result is p- or n-type thermoelectric material strips.

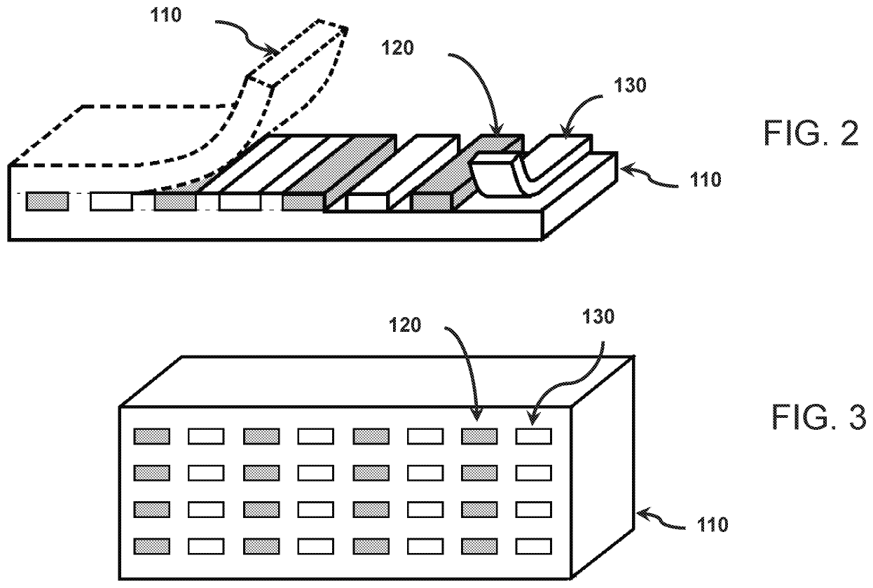

In some embodiments, as shown in FIG. 2, providing a sheet of alternating rows of parallel, spaced-apart ribbons of p- or n-type materials can include placing p-type material strips, 120, and n-type material strips, 130, in alternating order such that they are parallel and/or substantially equidistant from one another on a planar surface, 110. In some embodiments, providing a sheet of alternating rows of parallel spaced apart ribbons of p- or n-type materials can comprise affixing a plurality of alternative p- and n-type materials in substantially parallel and/or substantially equidistant from one another. In some embodiments, the p-type and/or n-type materials can be in the form of ribbons. In some embodiments, the width of the ribbons can be at least 4 times the thickness of the individual ribbons. In some embodiments, the ribbons can be about 5 mm wide by about 0.1 mm thick; where the thickness is the thickness of the thermoelectric slurry coating after sintering. In some embodiments, the ribbons can be spaced about 2.5 mm apart. In some embodiments, the ribbons can be spaced at about 50% of their respective width, e.g. if the ribbons are about 5.0 mm in width, they can be spaced about 2.5 mm apart. In some embodiments, the ribbons can be disposed substantially parallel to each other on a planar substrate. In some embodiments, the planar substrate can comprise an elastomer. In some embodiments, the elastomer can also be deposited in between the ribbons. In some embodiments, the method can also comprise applying a second, encapsulating layer, or second substrate, comprising an elastomer upon, between and/or around the thermoelectric material. In some embodiments, depositing the encapsulating layer can be by blade coating, spray coating, dip coating, spin coating, tape casting, chemical vapor deposition or other methods known by those skilled in the art. In some embodiments, the resulting coating can have a thickness ranging from about 50 μm to about 0.1 mm, or about 100 μm. In some embodiments, the elastomer can comprise poly(ethylene-vinyl acetate) (PEVA).

In some embodiments, the variation in distance between adjacent ribbons can be sufficient to prevent short circuiting between adjacent ribbons. For example, in some embodiments, for a 5 mm wide ribbon, the distance between the adjacent ribbons can be 2.5 mm. In some embodiments, the distance between adjacent ribbons of similar material can be about 100 μm. In some embodiments, the variation in the distance between adjacent ribbons of differing materials, e.g., p-type and n-type materials can be less than 25% of the width of the ribbon element. In some embodiments, an additional planar surface can be optionally applied on top of the alternating rows of parallel spaced apart ribbons of p- or n-type materials.

As shown in FIG. 3, in some embodiments, providing a sheet of alternating rows of parallel spaced apart ribbons of p- or n-type materials can further comprise stacking a plurality of sheets such that like p- and n-type materials on adjacent sheets overlap. In some embodiments, the plurality of sheets can be stacked such that like p- and n-type materials or are placed substantially over each other, for example more than 50% overlap. In some embodiments, plural sheets of parallel and/or substantially equidistantly positioned alternating ribbons of p- and n-type materials can be stacked upon each other. In some embodiments, the like p- and/or n-type materials are registered upon each other, e.g., p-type ribbons of one sheet are aligned and/or disposed over the p-type ribbons of a second sheet. In some embodiments, the particular materials are substantially aligned over like materials, for example p-type ribbons are aligned over p-type ribbons in separate sheet(s). In some embodiments, the particular materials center line of each ribbon can be within less than 10%, less than 25%, less than 50% offset from the ribbon disposed above and/or below the compared to ribbon, where offset is the relative displacement of the ribbons. In some embodiments, the ribbons of similar and/or same material can be disposed in substantially parallel stacks/columns of alternating materials. The result is a stack of plural sheets.

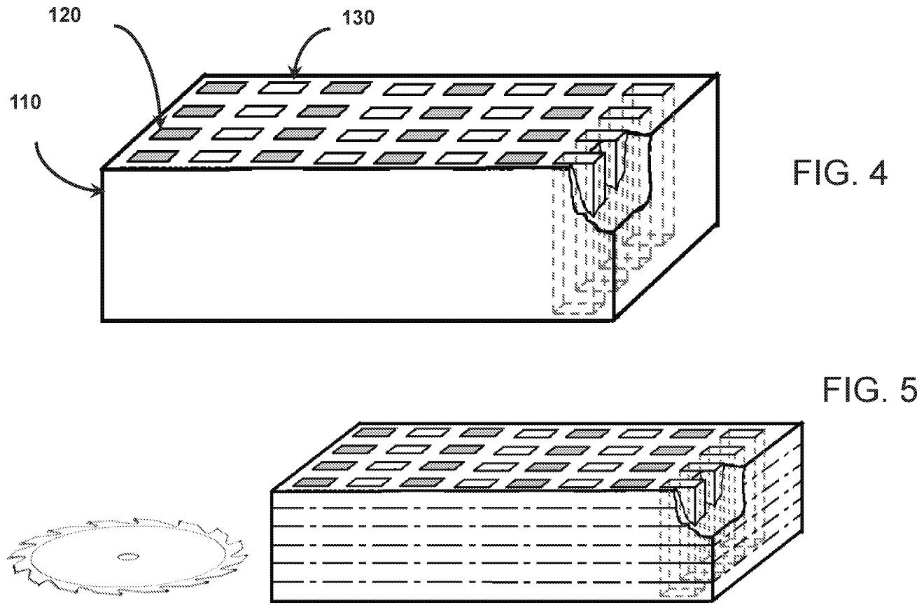

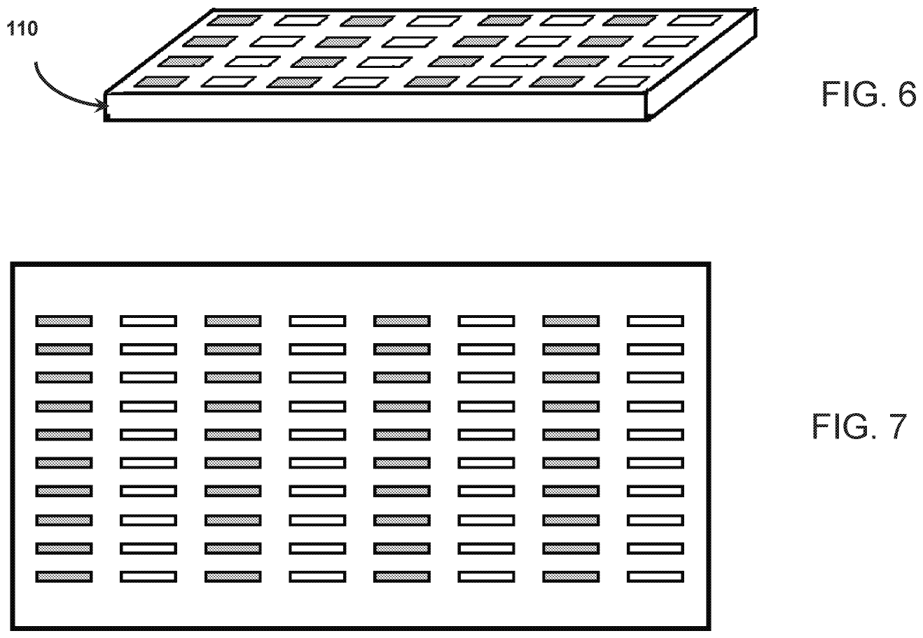

As shown in FIGS. 3 and 4, in some embodiments providing a sheet of alternating rows of parallel spaced apart ribbons of p- or n-type materials can comprise laminating and/or curing the stack of plural sheets while retaining the alternative p- and n-type sheets spatial relationships. In some embodiments, the registered or aligned p-type and n-type materials are laminated and/or cured while retaining the registered or aligned spatial relationship to affix the alternative p- and/or n-type materials relative each other. In some embodiments, laminating can comprise vacuum laminating the plural sheets such that the individual sheets meld together to become a single soft stack. In some embodiments, other forms of laminating known in the art can be used such as but not limited to pressure laminating can be used to remove spaces between the plural sheets by exerting force on the assembly to force pockets of interstitial space out of said assembly. In some embodiments, vacuum laminating can be done at a pressure of at most about 0.5 atm, at most about 0.1 atm, at most about 0.01 atm; to remove air bubbles between the individual sheets. In some embodiments, laminating can be done at a temperature of between about 60° C. to about 100° C., or about 85° C., for a time ranging from about 15 min to about 45 min, or about 20 min; so that the individual sheets meld together. In some embodiments, the soft stack is then cured. Curing the stack increases crosslinking and strengthens the soft material. In some embodiments, curing can be done at a temperature of about 100° C. to about 200° C., or about 150° C. for a time ranging from about 15 min to about 45 min, or about 20 min. The result is a thermoelectric stack.

As shown in FIG. 5, in some embodiments providing a sheet of alternating rows of parallel spaced apart ribbons of p- or n-type materials can comprise slicing the thermoelectric stack in an orthogonal orientation to the stack of plural sheets to create plural thermoelectric sheets. For example, if the width of the ribbon is considered the along the x-plane and the length of the ribbon considered along the y-plane, in one embodiment, the slicing of the ribbon/pseudoplanar sheet can occur in substantially the z-plane (see FIG. 5). In one embodiment, the x-y plane can in oriented substantially parallel to the direction of the generated current. In one embodiment, the x-y plane can in oriented substantially orthogonal to the direction of the generated current. In some embodiments, slicing the thermoelectric stack can be any means known by those skilled in the art including but not limited to mechanical sawing (e.g. cutting by blade), electrochemical sawing (e.g. etching, electrical discharge machining), or thermal (e.g. laser, flame cutting, plasma cutting). Cutting methods should be chosen such that the polymeric materials are not damaged in the process. In some embodiments, slicing the thermoelectric stack can be by a laser. In some embodiments, the thermoelectric stack can be sliced into sheets of a thickness ranging from about 0.5 mm to about 5 mm, or about 1 mm. The result is a thermoelectric sheet. In some embodiments, the plural ribbons encased within the thermoelectric sheet can be separated by layers or coatings of polymeric materials. In some embodiments, the polymeric materials can be non-conductive.

As shown in FIG. 7, in some embodiments, instead of rectilinear posts or legs, the p-type and/or n-type structures can be plural flat ribbon-like/pseudoplanar structures, the planes of the ribbon like structures being substantially orthogonal to the heat differential, and/or the ribbon structures having a substantially thinner parameter, e.g, thickness, than a post or leg. In other embodiments, the planarity of the plural flat ribbon-like structures can be substantially orthogonal to the direction of the generated current.

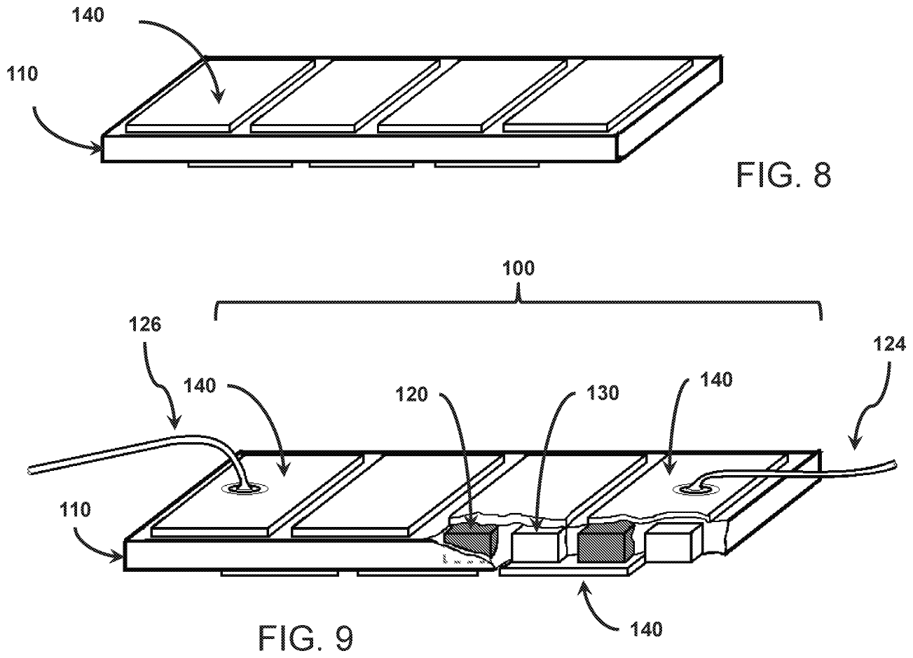

As shown in FIGS. 8 and 9, in some embodiments, the method can comprise positioning and/or electrically communicating an electrical connector, 140, in electrical communication with the plural n-type and/or p-type ribbons. In some embodiments, the method can comprise electrically connecting the electrical connectors with additional electrical connectors. In some embodiments, the electrical connectors used are known by those skilled in the art that have a low material resistance and low contact resistance as compared to the thermoelectric ribbon. In some embodiments, the electrical connector can comprise a metal or a metal oxide. In some embodiments, the electrical connect can comprise a silver paste or paint.

### Thermoelectric Device

In some embodiments, a thermoelectric device for providing electricity from a thermal differential can be described. In some embodiments, the aforementioned device can be made from the aforedescribed methods. In some embodiments, the device can be in the form of a sheet. In some embodiments, the sheet can be a flexible sheet.

As shown in FIGS. 8 and 9, in some embodiments, a thermoelectric device, 100, is described, the device being made according to the aforedescribed methods. In other embodiments, the thermoelectric device can be made by any methods known by those skilled in the art. In some embodiments, thermoelectric device can be generally planar. As shown in FIG. 9, In some embodiments, a thermoelectric device, 100, can be described as a sheet, the sheet comprising alternating rows of parallel columns of p-type materials, 120, and/or n-type materials, 130, where alternating rows electrically serially connected through connectors, 140. In some embodiments, the columns within each row are also connected electrically in parallel by the electrical connectors, 140.

As shown in FIG. 9, a first electrode, 124, and a second electrode, 126, can be in electrical communication with the thermoelectric device, 100. In some embodiments, a first electrode, 124, and a second electrode, 126, can be in electrical communication with the thermoelectric device, 100, via at least two electrical connectors, 140, and/or the plural layered p-type and/or n-type ribbon structures, 120 and 130. The thermoelectric device, 100, can comprise plural p-type ribbons (not shown) in alternating adjacent and/or spaced apart disposition with plural n-type ribbons (not shown). In some embodiments, thermoelectric device can generate a current across the first and second electrodes when there is a temperature difference between the higher temperature body and the lower temperature body of about 1 C or greater, about 5° C. or greater, about 50 C or greater, about 100° C. or greater, or about 200° C. or greater. A temperature differential between the higher and lower temperature bodies may be any temperature as long as the temperature does not cause melting of components or current interference in the thermoelectric device or module containing the described component. In some embodiments, the distance between the first side and the second side, or the thickness of the thermoelectric device, can be between about 0.5 mm to about 5 mm, or about 1 mm.

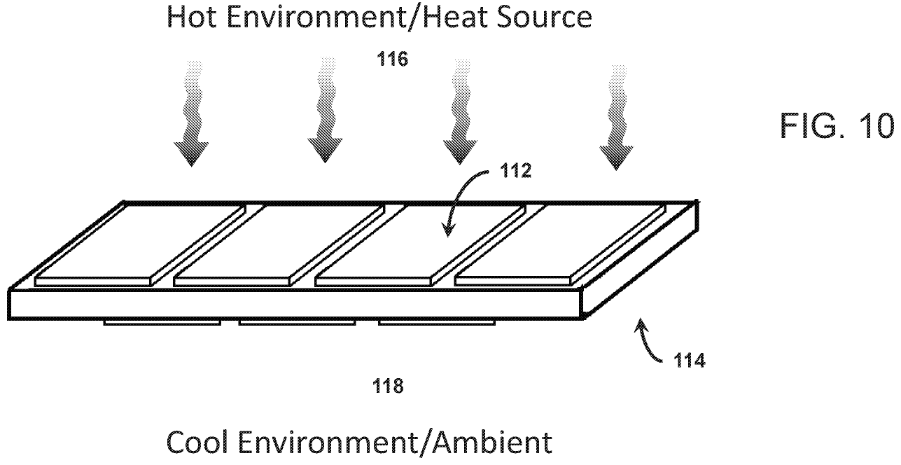

In some embodiments, as shown in FIG. 10, the thermoelectric device can comprise a planar thermoelectric layered composite, the planar composite having a first side, 112, and a second side, 114, the second side opposite the first side, the first side in thermal contact with a higher temperature body, 116, the second side in thermal contact with a lower temperature body, 118. Temperature bodies may be a solid body such as a heat pipe or heat strap, or they may be fluid bodies such as high temperature air or even low temperature air. The key is that a thermal gradient, with heat transfer, is created across the thermoelectric device. In some embodiments, the layered composite comprises plural alternating layers.

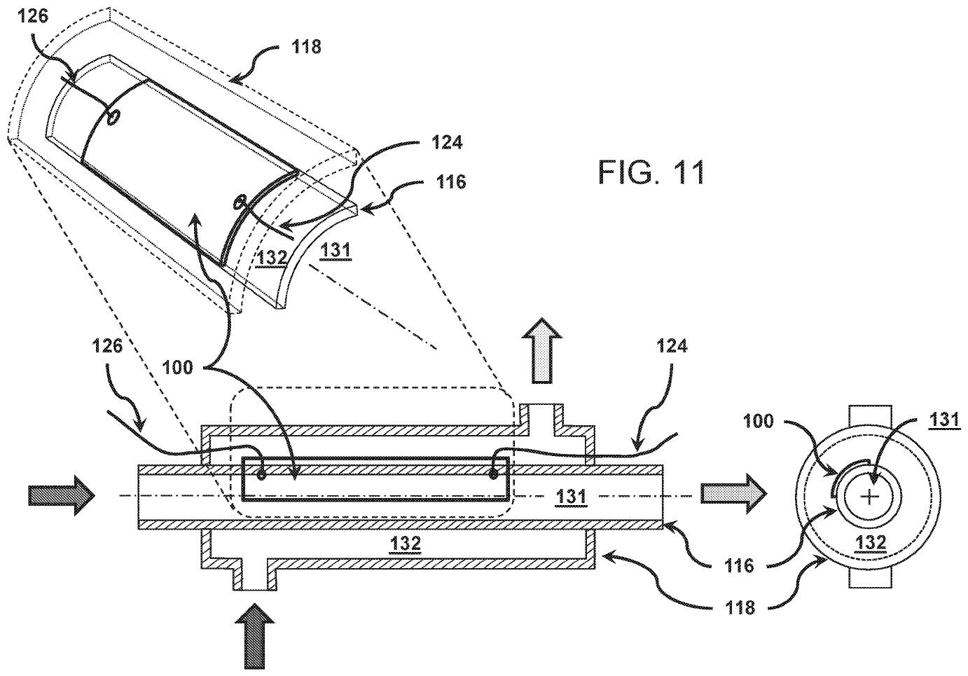

In some embodiments, as shown in FIG. 11, an embodiment of a thermoelectric device, 100, can be depicted. FIG. 11 depicts the thermoelectric device, 100, disposed in a plane substantially perpendicular to the direction of the heat differential between higher temperature body, 116, and the lower temperature body, 118. The thermoelectric device, 100, having electrodes 124 and 126 electrically connected on opposite ends, is disposed in thermal communication, indirectly or directly, with higher temperature body, 116, and the lower temperature body, 118. In some embodiments, the higher temperature body, 116, can be a first conduit or reservoir for passing or contacting or thermally communicating a high-temperature thermally conducting media to the thermoelectric device, 100. In some embodiments, the thermoelectric device can be in direct thermal communication with a high-temperature thermally conducting media. In some embodiments, the high-temperature thermally conducting media can be a gas or a liquid. In some embodiments, the liquid can be water. In one embodiment, the higher temperature body, 116, can be any thermally conductive material. In some embodiments, the thermally conductive material can be metal. In some embodiments, the conduit can be a metal pipe passing the higher temperature thermally conductive media, e.g., water, therethrough. Disposed on the second side of the composite thermoelectric device, 100, can be a lower temperature body, 118, and/or a low-temperature thermally conducting media. In some embodiments, the high-temperature body defines a first conduit, 131, and similarly the lower temperature body can define a second conduit. In some embodiments, a second conduit can coaxially receive the high-temperature body therein, defining an annulus, 132, between the high-temperature body and the low-temperature body. In some embodiments, low-temperature thermally conducting media, e.g., cool water can pass through the annulus, 132, such that the thermoelectric device, 200, is disposed between the high temperature body, 116, and low-temperature thermally conducting media resulting in heat transfer through the device.

In some embodiments, one of the first electrode and the second electrode may be electrically connected to a power supply, or electrically connected to the outside of a thermoelectric module, for example, to an electric device which consumes or stores electric power, e.g. a battery.

### EXAMPLES

It has been discovered that embodiments of the thermoelectric devices and methods for making the same described herein improve the flexibility and/or thinness of the aforementioned thermoelectric devices. These benefits are further shown by the following examples, which are intended to be illustrative of the embodiments of the disclosure, but are not intended to limit the scope or underlying principles in any way.

Preparation of a thermoelectric metal tape can be carried out in at least two ways: (1) modifying a substrate by adding a thermoelectric coating and then cutting or slicing the resulting composite sheet to obtain a tape or (2) coating pre-sliced substrates. It may be better to coat a large substrate and then to cut the coating into the desired width because it is important that the tape edges are kept clean/bare for electrical communication.

### Example 1

### Synthesis of the Thermoelectric Materials

Fabrication of the p-type Thermoelectric Compound (Bi_{0.5}Sb_{1.5}Te₃): Elemental shots of Bi (1-12 mm, 99.999%, Aldrich, St. Louis, Mo. USA), Sb (6 mm, 99.999%, Alfa Aesar, Ward Hill, Mass. USA), and Te (4-5 mm, 99.999%, Aldrich) were selected as starting materials for mechanical alloying (MA). MA was carried out in a planetary ball mill machine (SFM-1, MTI Corp., Richmond, Calif. USA) at a rotation speed of 500 rpm. A stainless container (MTI Corp.) with a valve inlet, and stainless balls were utilized. About 15 g of the elemental shots (Bi: 2.34 g, Sb: 4.09 g and Te: 8.57 g) was put in the container with about 162 g stainless steel balls (3 of 20 mm ϕ (33.1 g), 3 of 15 mm ϕ (13.7 g), 6 of 8 mm ϕ (2.1 g) and 10 of 6 mm ϕ (0.9 g)), and then evacuation and argon purging were repeated 5 times to replace the air with argon (Airgas, San Marcos, Calif. USA). Finally, the container was filled with argon (Airgas), and the valve was tightly closed. Four sets of MA were simultaneously performed continuously for 96 hours without interruption. Recovery was greater than 99%. The obtained powder (about 4×15 g) was mixed for 10 minutes in an acoustic mixer (LabRAM, Resodyn Acoustic Mixer, Inc., MT, USA) to average the above 4 sets. The result was a p-type thermoelectric powder.

Fabrication of the n-type Thermoelectric Compound (Bi₂Sb_{0.3}Te_{2.7}): Elemental shots of Bi (99.999%, Aldrich), Se (less than 5 mm, 99.999%, Aldrich) and Te (99.999%, Aldrich) were selected as starting materials for MA. MA was carried out in a planetary ball mill machine (SFM-1, MTI Corp.) at a rotation speed of 500 rpm. A stainless container with a valve inlet and stainless steel balls were utilized. About 15 g of the elemental shots (Bi: 7.97 g, Se: 0.45 g and Te: 6.58 g) was put in the container with about 162 g balls (3 of 20 mm ϕ (33.1 g), 3 of 15 mm ϕ (13.7 g), 6 of 8 mm ϕ (2.1 g) and 10 of 6 mm ϕ (0.9 g)), and then evacuation and argon purging were repeated 5 times to replace the air with argon (Airgas). Finally, the container was filled with argon (Airgas), and the valve was tightly closed. Four sets of MA were simultaneously performed continuously for 96 hours without interruption. Recovery was greater than 99%. The obtained powder (about 4×15 g) was acoustically mixed (LabRAM, Resodyn Acoustic Mixer, Inc.) for 10 minutes to average the above 4 sets. The result was an n-type thermoelectric powder.

Ball milling of the powder: The thermoelectric powders were further ball-milled in a sintered corundum container. Each powder was separated into four batches, all batches undergoing the process simultaneously. About 15 g of thermoelectric powder was put in the container with zirconia balls (˜165 pieces of 0.09 g balls and 5 pieces of 0.42 g balls) and 25 mL of 2-propanol (Aldrich), and then ball milling was carried out at a rotation speed of ˜300 rpm for 5 hours. After ball milling, the balls were separated with a strainer, and then dried at 110° C. overnight. The dried thermoelectric powder was then further dried at 100° C. under vacuum conditions for 1 hour. All four batches of 15 g ball-milled powder were then mixed acoustically (LabRAM, Resodyn Acoustic Mixer, Inc.) for 10 minutes to average the batches for each powder.

Creation of the Slurries: A slurry was prepared by mixing the appropriate amount of the thermoelectric powder (p-type or n-type) and the premade binder solution (10-20 wt % of poly(vinylidene fluoride-co-hexafluoropropylene), P-(VDF/HFP) (Aldrich) in dimethylformamid (DMF)) where the mass ratios were about 1:0.075:0.67 (thermoelectric powder:P(VDF-HFP):DMF) The resulting mixture was then placed in an acoustic mixer (LabRAM, Resodyn Acoustic Mixers) for 30 minutes. Then, the resulting mixture was sonicated in a water bath for 2 hours to separate amassed particles. The result was a thermoelectric slurry (p-type or n-type).

Creating a Coating: The thermoelectric slurry (p-type or n-type) was then cast on a releasing substrate, e.g., 0.003″ thick Kapton® HN film (3 mil, CS Hyde Company, Lake Villa, Ill. USA) using a square applicator (Paul N. Gardner Company, Inc., Pompano Beach, Fla. USA) with a gap of 4-15 mil (100-380 μm) at a cast rate of about 5 cm/second. After brief drying in air, the casted film was dried at 100° C. in vacuum for 1 hour. The result was a thermoelectric form (p-type or n-type).

Sintering the Coating to Create a Thermoelectric Form: The thermoelectric forms (p-type or n-type) were then sintered. First, the thermoelectric form was cut into 0.5 cm×2.5 cm, and then was hot-pressed at 150° C. at 800 MPa for 30 second. As a result, an approximately 50 μm thick thermoelectric film was obtained. The film was then annealed in a Pyrex tube in a tube furnace in 97% N₂/3% H₂ atmosphere at a ramp rate of 3° C./min to 375° C. and held for 2 hours for p-type materials. For n-type materials, the ramp rate was set to 3° C./min to 325° C. and held for 2 hours. The result was a thermoelectric material (p-type or n-type).

### Example 1.2

### Fabrication of Thermoelectric Devices

Creating a Stack of Plural Sheets: First, the two types of thermoelectric materials, p-type and n-type) were placed in parallel on a PEVA substrate (0.46 mm thick Photocap®, Specialized Technology Resources, Inc., Enfield, Conn. USA) at 75° C. such that they spanned the substrate, alternating material types, with a separation of about 2.5 mm. This process was repeated a total of four times to provide five identical sheets which were then stacked such that the individual strips of thermoelectric materials were stacked on top of each other. The result was a stack of plural sheets.

Laminating to Form one Thermoelectric Stack: Then, the stack of plural sheets was laminated to create one large continuous stack. The sheets were vacuum laminated using a module laminator (LM series, NPC Incorporated, Tokyo, Japan) set to an atmosphere of 0.002 atm at a temperature of 85° C. for 20 minutes. Then, the resulting stack was cured in situ at standard atmosphere at a temperature of about 150° C. for 15 minutes to harden the PEVA. The result was a thermoelectric stack.

Slicing the Stack to Create Multiple Thermoelectric Elements: The thermoelectric stack was then laser-cut in 1 mm thick layers using a laser engraving and cutting system (VLS 2.30, Universal Laser Systems) with a 25 W CO₂ laser. The results were thermoelectric sheets.

Electrically Connecting the Thermoelectric Materials to Create Thermoelectric Devices: Then for each sheet, the exposed thermoelectric materials on the surface of the sheets were coated with silver paint (Ted Pella, Redding, Calif. USA) in a manner that connected stacked-like thermoelectric materials in parallel to create rows. Then, the silver paint was further applied between the rows to connect the alternating rows in series. The result was a thermoelectric device.

### Example 1.3

### Application and Measurement of a Thermoelectric Device

A thermoelectric device in a setup similar to the schematic depicted in FIG. 11 was constructed. A 5 layer composite thermoelectric device, made as described in Example 1.2, was disposed approximately in the middle upon the outer surface of a 12 inch section of copper pipe having an inner diameter of about 1 inch. A polycarbonate sleeve having a thickness of about ⅛ of an inch and an inner diameter of about 1.5 inches was coaxially positioned over the thermoelectric device and held in place by annular rubber stoppers to define a concentric and coaxial annulus. The annular space was communicated via inlets to the outside to pass cold water, having a temperature of about 40° C., in through one outlet and out the other. Hot water, having a temperature of about 55° C., was then concurrently passed through the internal copper conduit, creating a temperature differential of about 40° C. An ammeter/voltmeter (HHM35, Omega Engineering, Inc., Stamford Conn. USA) was connected to the first and second electrodes. The ammeter registered a voltage of about 6 mV generated by the thermoelectric device for a temperature difference of 15° C.

### Embodiments

The following embodiments are specifically contemplated by the authors of the present disclosure:
Embodiment 1. A method for making a thermoelectric device, comprising:
(1) providing a sheet of alternating rows of parallel columns of p- or n-type thermoelectric materials; and
(2) electrically communicating the parallel columns such that within each row the columns are connected in parallel but the rows are connected in series.
Embodiment 2. The method of embodiment 1, wherein the p-type thermoelectric materials comprise Bi_{0.5}Sb_{1.5}Te₃.
Embodiment 3. The method of embodiment 1 or 2, wherein the n-type thermoelectric materials comprise Bi₂Se_{0.3}Te_{2.7}.
Embodiment 4. The method of embodiment 1, 2, or 3, wherein the both the p-type and the n-type thermoelectric materials comprise poly(vinylidene fluoride co-hexafluoro-propylene) or P(VDF-HFP).
Embodiment 5. The method of embodiment 1, 2, 3, or 4, wherein providing a sheet of alternating rows of parallel columns of p- or n-type thermoelectric materials comprises creating p- or n-type thermoelectric material strips by: (1) hot pressing either p- or n-type thermoelectric materials; and (2) annealing the resulting materials.
Embodiment 6. The method of embodiment 5, wherein the hot pressing is performed at a pressure of about 600 MPa to about 1000 MPa.
Embodiment 7. The method of embodiment 5 or 6, wherein the hot pressing is performed at a temperature of about 100° C. to about 250° C.
Embodiment 8. The method of embodiment 5, 6, or 7, wherein the hot pressing is performed for a period of about 10 seconds to about 12 hours.
Embodiment 9. The method of embodiment 5, 6, 7, or 8, wherein the annealing is performed at a temperature of about 275° C. to about 400° C.
Embodiment 10. The method of embodiment 5, 6, 7, 8 or 9, wherein the annealing is performed for a period of about 30 minutes to about 6 hours.
Embodiment 11. The method of embodiment 5, 6, 7, 8, 9, or 10, wherein the annealing is performed in a reducing atmosphere.
Embodiment 12. The method of embodiment 1, 2, 3, or 4, wherein providing a sheet of alternating rows of parallel columns of p- or n-type thermoelectric materials comprises creating p- or n-type thermoelectric material strips by: (1) hot pressing either p- or n-type thermoelectric materials at a temperature of about 120° C. to about 180° C. for a period of about 20 seconds to about 5 minutes at a pressure of about 750 MPa to about 850 MPa; and (2) annealing the resulting materials at a temperature of about 300° C. to about 400° C. for a period of about 60 minutes to about 4 hours in a reducing atmosphere.
Embodiment 13. The method of embodiment 1, 2, 3, 4, 5, 6, 7, 8, 9, 10, 11, or 12, wherein providing a sheet of alternating rows of parallel columns of p- or n-type thermoelectric materials comprises placing alternate p- and n-type thermoelectric material strips in parallel and substantially equidistant from one another on a substrate
Embodiment 14. The method of embodiment 13, wherein the substrate is a planar surface.
Embodiment 15. The method of embodiment 13, wherein providing a sheet of alternating columns of parallel sheets of p- or n-type thermoelectric materials comprises affixing the alternating p- and n-type materials in parallel and substantially equidistant from each other.
Embodiment 16. The method of embodiment 13, wherein providing a sheet of alternating columns of parallel sheets of p- or n-type thermoelectric materials comprises stacking plural sheets to overlap like p- and n-type material on adjacent sheets.
Embodiment 17. The method of embodiment 16, wherein providing a sheet of alternating columns of parallel sheets of p- or n-type thermoelectric materials comprises laminating the stack of plural sheets while retaining the alternative p- and n-type sheets spatial relationships at a temperature of about 60° C. to about 100° C. for a period of about 15 minutes to about 45 minutes.
Embodiment 18. The method of embodiment 17, wherein providing a sheet of alternating columns of parallel sheets of p- or n-type thermoelectric materials comprises subsequently curing the stack of plural sheets while retaining the alternative p- and n-type sheets spatial relationships, the curing occurring at a temperature of about 100° C. to about 200° C. for a period of about 15 minutes to about 45 minutes.
Embodiment 19. The method of embodiment 18, wherein providing a sheet of alternating columns of parallel sheets of p- or n-type thermoelectric materials comprises slicing the stacked plural sheets in an orthogonal orientation relative to the stack to create plural thermoelectric sheets.
Embodiment 20. A thermoelectric sheet device made according to the method of embodiment 1, 2, 3, 4, 5, 6, 7, 8, 9, 10, 11, 12, 13, 14, 15, 16, 17, 18, or 19.
Embodiment 21. A thermoelectric sheet device comprising alternating rows of parallel columns of p- or n-type materials, where said columns within each row are connected electrically in parallel and alternating rows are electrically connected in series.

Unless otherwise indicated, all numbers expressing quantities of ingredients, properties such as molecular weight, reaction conditions, and so forth used in the specification and claims are to be understood as being modified in all instances by the term “about.” Accordingly, unless indicated to the contrary, the numerical parameters set forth in the specification and attached claims are approximations that may vary depending upon the desired properties sought to be obtained. At the very least, and not as an attempt to limit the application of the doctrine of equivalents to the scope of the claims, each numerical parameter should at least be construed in light of the number of reported significant digits and by applying ordinary rounding techniques.

The terms “a,” “an,” “the” and similar referents used in the context of describing the invention (especially in the context of the following claims) are to be construed to cover both the singular and the plural, unless otherwise indicated herein or clearly contradicted by context. All methods described herein can be performed in any suitable order unless otherwise indicated herein or otherwise clearly contradicted by context. The use of any and all examples, or exemplary language (e.g., “such as”) provided herein is intended merely to better illuminate the invention and does not pose a limitation on the scope of any claim. No language in the specification should be construed as indicating any non-claimed element essential to the practice of the invention.

Groupings of alternative elements or embodiments disclosed herein are not to be construed as limitations. Each group member may be referred to and claimed individually or in any combination with other members of the group or other elements found herein. It is anticipated that one or more members of a group may be included in, or deleted from, a group for reasons of convenience and/or patentability. When any such inclusion or deletion occurs, the specification is deemed to contain the group as modified thus fulfilling the written description of all Markush groups used in the appended claims.

Certain embodiments are described herein, including the best mode known to the inventors for carrying out the invention. Of course, variations on these described embodiments will become apparent to those of ordinary skill in the art upon reading the foregoing description. The inventor expects skilled artisans to employ such variations as appropriate, and the inventors intend for the invention to be practiced otherwise than specifically described herein. Accordingly, the claims include all modifications and equivalents of the subject matter recited in the claims as permitted by applicable law. Moreover, any combination of the above-described elements in all possible variations thereof is contemplated unless otherwise indicated herein or otherwise clearly contradicted by context.

In closing, it is to be understood that the embodiments disclosed herein are illustrative of the principles of the claims. Other modifications that may be employed are within the scope of the claims. Thus, by way of example, but not of limitation, alternative embodiments may be utilized in accordance with the teachings herein. Accordingly, the claims are not limited to embodiments precisely as shown and described.

1. A method for making a thermoelectric device, comprising:
a. providing a sheet of alternating rows of parallel columns of p- or n-type thermoelectric materials; and
b. electrically communicating the parallel columns such that within each row the columns are connected in parallel but the rows are connected in series.

2. The method of claim 1, wherein the p-type thermoelectric materials comprise Bi_{0.5}Sb_{1.5}Te₃.

3. The method of claim 1, wherein the n-type thermoelectric materials comprise Bi₂Se_{0.3}Te_{2.7}.

4. The method of claim 1, wherein the both the p-type and the n-type thermoelectric materials comprise poly(vinylidene fluoride co-hexafluoro-propylene) or P(VDF-HFP).

5. The method of claim 1, wherein providing a sheet of alternating rows of parallel columns of p- or n-type thermoelectric materials comprises creating p- or n-type thermoelectric material strips by: (1) hot pressing either p- or n-type thermoelectric materials; and (2) annealing the resulting materials.

6. The method of claim 5, wherein the hot pressing is performed at a pressure of about 600 MPa to about 1000 MPa.

7. The method of claim 6, wherein the hot pressing is performed at a temperature of about 100° C. to about 250° C.

8. The method of claim 7, wherein the hot pressing is performed for a period of about 10 seconds to about 12 hours.

9. The method of claim 8, wherein the annealing is performed at a temperature of about 275° C. to about 400° C.

10. The method of claim 9, wherein the annealing is performed for a period of about 30 minutes to about 6 hours.

11. The method of claim 10, wherein the annealing is performed in a reducing atmosphere.

12. The method of claim 1, wherein providing a sheet of alternating rows of parallel columns of p- or n-type thermoelectric materials comprises creating p- or n-type thermoelectric material strips by: (1) hot pressing either p- or n-type thermoelectric materials at a temperature of about 120° C. to about 180° C. for a period of about 20 seconds to about 5 minutes at a pressure of about 750 MPa to about 850 MPa; and (2) annealing the resulting materials at a temperature of about 300° C. to about 400° C. for a period of about 60 minutes to about 4 hours in a reducing atmosphere.

13. The method of claim 1, wherein providing a sheet of alternating rows of parallel columns of p- or n-type thermoelectric materials comprises placing alternate p- and n-type thermoelectric material strips in parallel and substantially equidistant from one another on a substrate

14. The method of claim 13, wherein the substrate is a planar surface.

15. The method of claim 13, wherein providing a sheet of alternating columns of parallel sheets of p- or n-type thermoelectric materials comprises affixing the alternating p- and n-type materials in parallel and substantially equidistant from each other.

16. The method of claim 13, wherein providing a sheet of alternating columns of parallel sheets of p- or n-type thermoelectric materials comprises stacking plural sheets to overlap like p- and n-type material on adjacent sheets.

17. The method of claim 16, wherein providing a sheet of alternating columns of parallel sheets of p- or n-type thermoelectric materials comprises laminating the stack of plural sheets while retaining the alternative p- and n-type sheets spatial relationships at a temperature of about 60° C. to about 100° C. for a period of about 15 minutes to about 45 minutes.

18. The method of claim 17, wherein providing a sheet of alternating columns of parallel sheets of p- or n-type thermoelectric materials comprises subsequently curing the stack of plural sheets while retaining the alternative p- and n-type sheets spatial relationships, the curing occurring at a temperature of about 100° C. to about 200° C. for a period of about 15 minutes to about 45 minutes.

19. The method of claim 18, wherein providing a sheet of alternating columns of parallel sheets of p- or n-type thermoelectric materials comprises slicing the stacked plural sheets in an orthogonal orientation relative to the stack to create plural thermoelectric sheets.

20. A thermoelectric sheet device made according to the method of claim 1.

21. A thermoelectric sheet device comprising alternating rows of parallel columns of p- or n-type materials, where said columns within each row are connected electrically in parallel and alternating rows are electrically connected in series.
